(19) United States
(12) Patent Application Publication
(10) Pub. No.: US 2015/0095564 A1
(43) Pub. Date: Apr. 2, 2015

(54) APPARATUS AND METHOD FOR SELECTING MEMORY OUTSIDE A MEMORY ARRAY

(71) Applicants: Melvin K. Benedict, Magnolia, TX (US); Eric L. Pope, Tomball, TX (US); Guy E. McSwain, Cypress, TX (US); Joseph W. Fahy, Houston, TX (US); Maurizio Contini, Belmont, MA (US)

(72) Inventors: Melvin K. Benedict, Magnolia, TX (US); Eric L. Pope, Tomball, TX (US); Guy E. McSwain, Cypress, TX (US); Joseph W. Fahy, Houston, TX (US); Maurizio Contini, Belmont, MA (US)

(21) Appl. No.: 14/396,600

(22) PCT Filed: May 9, 2012
(86) PCT No.: PCT/US2012/037009

§ 371 Date: Oct. 23, 2014

(51) Int. Cl. G11C 7/10; G11C 11/406

(52) U.S. Cl. CPC G11C 7/1072; G11C 11/40615
USPC 711/105

(57) ABSTRACT

An apparatus includes a memory module, which includes a memory array. The memory array includes rows of memory and columns of memory. The apparatus also includes at least one row of memory not in the memory array and a register. The register includes an address space and a row/column indicator. The apparatus also includes row selection logic to select the at least one row to be activated if the address from an address bus equals the register value and if the row/column indicator indicates row.

### BACKGROUND

During many tasks performed by a computer, data is stored or retrieved from system memory. Two types of system memory are cache memory, which may comprise fast static random access memory (“SRAM”) integrated with the processor, and main memory, which may comprise dynamic random access memory (“DRAM”) chips on dual inline memory modules (“DIMMs”). Each DRAM chip may contain memory locations, or cells, arranged in a matrix of rows and columns. A DRAM cell contains a capacitor capable of storing an electrical charge for a short time. A charged cell represents a “1” data bit, and an uncharged cell represents a “0” data bit. To maintain the validity of the stored bits, the capacitors are recharged or refreshed thousands of times per second. As such, DRAM is considered volatile memory.

### BRIEF DESCRIPTION OF THE DRAWINGS

For a detailed description of exemplary embodiments of the invention, reference will now be made to the accompanying drawings in which:

FIG. 1 illustrates an apparatus for selecting memory outside a memory array in accordance with at least some illustrated examples;

FIG. 2 illustrates a method for selecting memory outside a memory array in accordance with at least some illustrated examples;

FIG. 3 shows a logic diagram for selecting memory outside a memory array in accordance with at least some illustrated examples; and

FIG. 4 illustrates an apparatus for selecting memory outside a memory array in accordance with at least some illustrated examples.

### DETAILED DESCRIPTION

When a memory controller accesses a memory cell, it sends electronic address signals that specify the target cell's row address and column address. The memory controller sends these signals to the memory through a memory bus, which may comprise an address bus, a command bus, and a data bus. The address bus may be combined with the command bus to form an address/command bus. The data bus is a set of lines, or traces, that carry data to and from the memory. Each trace may carry one data bit at a time. The throughput, or bandwidth, of the data bus depends on its width in bits. For example, the data width of a memory bus may be 64-bits, which means that the bus has 64 traces, each of which transports one bit at a time. Each 64-bit unit of data may be called a data word.

The address portion of the address/command bus may comprise a set of traces that carry signals identifying the location of data in memory. The command portion of the address/command bus may convey what instruction is to be performed such as read, write, or refresh. When writing data to a cell, the memory controller may select the data's row by first strobing the row address onto the address/command bus. Next, the location may be pinpointed in the row by strobing the column address onto the address/command bus. The memory controller may then move the data onto the data bus, and the memory may store the data in the cells.

Memory modules, memory chips, and memory banks may contain rows and columns of memory that are not part of the main memory arrays. That is, spare rows and columns of memory may be provided that are unused in error-free operation. These spare rows and columns may be used as replacement rows and columns thus correcting or bypassing defects in the main memory arrays. Accordingly, as more errors can be tolerated or corrected, the life of the modules, chips, and banks may be increased.

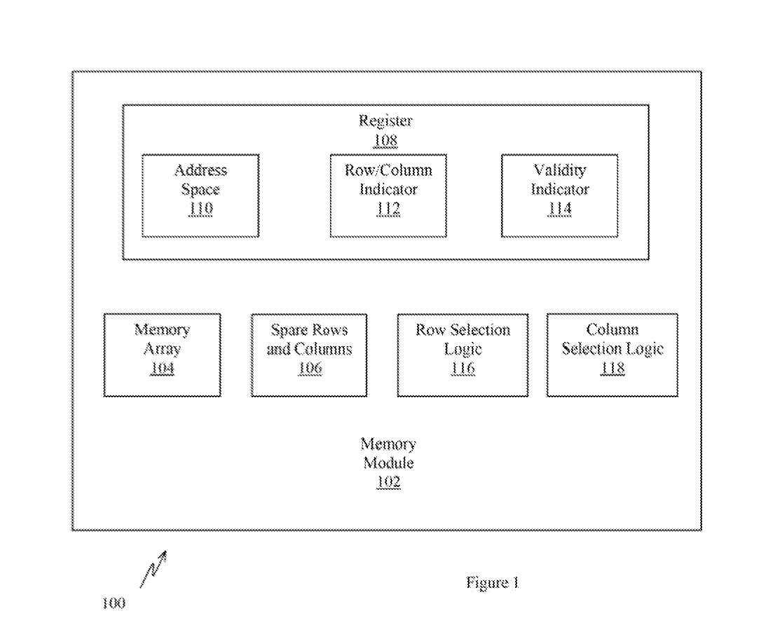

FIG. 1 illustrates an apparatus 100 for selecting memory outside a memory array. The apparatus 100 may comprise a memory module 102, and the memory module 102 may comprise a memory array 104 used to store data or instructions in at least one example. The memory array 104 may comprise errors or defects, which may be caused by several events or conditions. Because memory errors are commonly classified according to the number of bits affected, an error in one bit of data is a single-bit error. An error in more than one bit of data is a multi-bit error. Memory errors may also be classified as “hard” or “soft” errors. Manufacturing defects, bad solder joints, and data pin issues cause “hard” errors because the memory array 104 consistently returns incorrect results. For example, a “stuck” memory cell returns the same bit value, even when a different bit was written to it. In contrast, soft errors are transient and non-repeating. They can be caused by an electrical disturbance inside the capacitor array, and can occur randomly. For example, if an external event affects the charge of a capacitor, the data in the capacitor may become incorrect. Errors and defects may cause applications and operating systems using the memory module 102 to crash, sometimes resulting in permanent data loss.

The memory module 102 may also comprise spare rows and columns of memory 106. In at least one example, these rows and columns 106 may be provided by the manufacturer for test purposes, and may be mapped into the memory array 104 by the manufacturer via fusible links if a defect is detected during manufacturing. However, if not used, the rows and columns are not removed from the memory module 102, but can be treated as spares. The spare rows and columns of memory 106 may provide backup to defective or error-prone rows and columns of the main memory array 104. For example, when a row in the memory array 104 is detected as defective, the row's contents may be written into a spare row 106. Afterwards, accesses to the defective row are diverted to the spare row including reads, writes, and refreshes. Accordingly, the defective row need not be error corrected, and the memory module 102 need not be replaced.

The memory module 102 may also comprise a register 108, which may comprise an address space 110, a row/column indicator 112, and a validity indicator 114. In at least one example, the register 108 is created for the memory module 102. The address space 110 may be used to contain addresses of defective or error-prone locations in the memory array 104 in at least one example. The validity indicator 114 may comprise a flag or a bit that indicates if the address in the address space 110 is valid. For example, the flag or bit may be marked or set to 1 if the address contained in the address space 110 is a valid reference to a location in the memory array 104. The flag or bit may be cleared or set to 0 if the address contained in the address space 110 is not a valid reference to a location in the memory array 104. Similarly, the row/column indicator may be a flag, bit, or set of bits that indicate if the address in address space 110 refers to a row or column.

The memory module 102 may also comprise row selection logic 116 and column selection logic 118. In at least one example, row selection logic 116 selects the spare row to be activated in place of the defective row if one or more conditions are met. The conditions may include: a received address from the address bus equals the value in the address space 110 of the register, the row/column indicator indicates row, the validity indicator indicates a valid register value in the address space 110, and an activate state is commanded for the memory array.

Similarly, column selection logic 118 may select the spare column to read from or written to in place of a defective column if one or more conditions are met. The conditions may include: a received address from the address bus equals the value in the address space 110 of the register, the row/column indicator indicates column, the validity indicator indicates a valid register value in the address space 110, and a read/write state is commanded for the memory array.

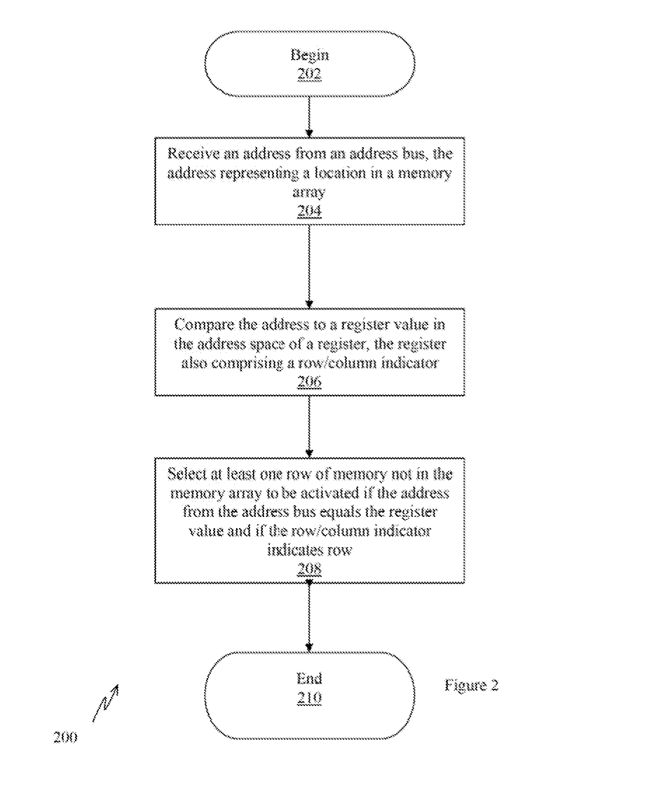

FIG. 2 illustrates a method 200 of selecting memory outside a memory array beginning at 202 and ending at 210. In at least one example, the steps of the method 200 are performed by a memory controller or processor. At 204, an address representing a location in a memory array may be received. The address may be received through an address bus in at least one example. At 206, the address may be compared to a register value in the address space of a register. The address space may be 16 bits in at least one example, and an address of a defective column or row may have been written into the register in accordance with the method 200. The register may also include a row/column indicator and a validity indicator. The validity indicator may comprise a flag or a bit that indicates if the address in the address space is valid. For example, the flag or bit may be marked or set to 1 if the address contained in the address space is a valid reference to a location in the memory array. The flag or bit may be cleared or set to 0 if the address contained in the address space is not a valid reference to a location in the memory array. Similarly, the row/column indicator may be a flag, bit, or set of bits that indicate if the address in address space refers to a row or column.

At 208, a spare row may be selected to be activated in place of the defective row if one or more conditions are met. The conditions may include: the received address from the address bus equals the value in the address space of the register, the row/column indicator indicates row, the validity indicator indicates a valid register value in the address space, and an activate state is commanded for the memory array. Similarly, a spare column may be selected to be read from or written to in place of a defective column if one or more conditions are met. The conditions may include: a received address from the address bus equals the value in the address space of the register, the row/column indicator indicates column, the validity indicator indicates a valid register value in the address space, and a read/write state is commanded for the memory array.

In at least one example, the method 200 further comprises writing the contents of the failed row or column of the memory array into the selected spare row or column. Subsequent reads or writes may be directed to the spare row or column instead of the defective row or column. Also, an inventory of rows and columns of memory not in the memory array may be maintained to allow multiple rows and columns of defective memory to be replaced by spare rows and columns.

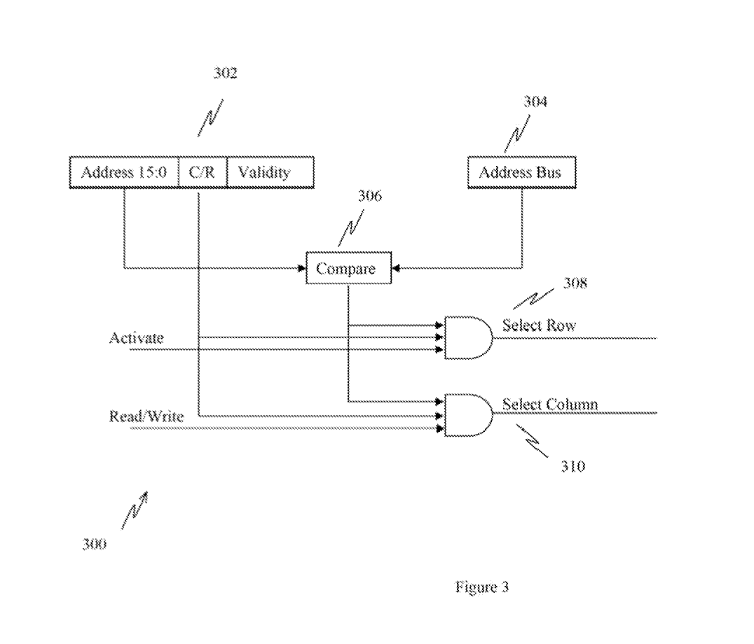

FIG. 3 shows a logic diagram 300 for selecting memory outside a memory array. A register 302 may comprise an address space, a row/column indicator, and a validity indicator. The address space may be used to contain addresses of defective or error-prone locations in a memory array in at least one example. The validity indicator may comprise a flag or a bit that indicates if the address in the address space is valid. For example, the flag or bit may be marked or set to 1 if the address contained in the address space is a valid reference to a location in the memory array. The flag or bit may be cleared or set to 0 if the address contained in the address space is not a valid reference to a location in the memory array. Similarly, the row/column indicator may be a flag, bit, or set of bits that indicate if the address in address space refers to a row or column.

Row selection logic 308 may be a logical AND in at least one example. In other examples, other circuit logic may be used depending on the combination of conditions desired for selecting spare rows. In at least one example, row selection logic 308 selects the spare row to be activated in place of the defective row if one or more conditions are met. The conditions may include: a received address from the address bus 304 equals the value in the address space of the register 302 as calculated by comparison logic 306, the row/column indicator indicates row, the validity indicator indicates a valid register value in the address space, and an activate state is commanded for the memory array.

Similarly, column selection logic 310 may be a logical AND in at least one example. In other examples, other circuit logic may be used depending on the combination of conditions desired for selecting spare columns. In at least one example, column selection logic 310 selects the spare column to be read from or written to in place of the defective column if one or more conditions are met. The conditions may include: a received address from the address bus 304 equals the value in the address space of the register 302 as calculated by comparison logic 306, the row/column indicator indicates column, the validity indicator indicates a valid register value in the address space, and a read/write state is commanded for the memory array.

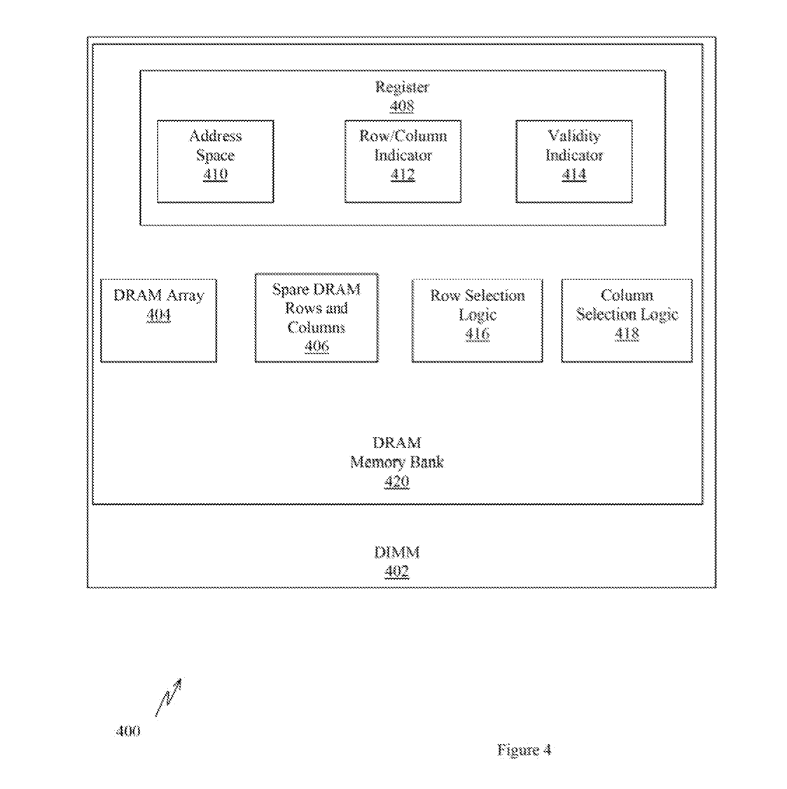

FIG. 4 illustrates an apparatus 400 for selecting memory outside a memory array. The apparatus 400 may comprise dual inline memory module (“DIMM”) 402, which may comprise a DRAM memory bank 420. The DRAM memory bank 402 may comprise a DRAM array 404 used to store data or instructions in at least one example. The DRAM array 404 may comprise errors or defects, which may be caused by several events or conditions. Because memory errors are commonly classified according to the number of bits affected, an error in one bit of data is a single-bit error. An error in more than one bit of data is a multi-bit error. Memory errors may also be classified as “hard” or “soft” errors. Manufacturing defects, bad solder joints, and data pin issues cause “hard” errors because the DRAM array 404 consistently returns incorrect results. For example, a “stuck” memory cell returns the same bit value, even when a different bit was written to it. In contrast, soft errors are transient and non-repeating. They can be caused by an electrical disturbance inside the capacitor array, and can occur randomly. For example, if an external event affects the charge of a capacitor, the data in the capacitor may become incorrect. Errors and defects may cause applications and operating systems using the DIMM 402 to crash, sometimes resulting in permanent data loss.

The DIMM 402 may also comprise spare rows and columns of memory 406. In at least one example, these rows and columns 406 may be provided by the manufacturer for test purposes, and may be mapped into the DRAM array 404 by the manufacturer via fusible links if a defect is detected during manufacturing. However, if not so used, the rows and columns are not removed from the DIMM 402, but can be treated as spares. The spare rows and columns of memory 406 may provide backup to defective or error-prone rows and columns of the DRAM array 404. For example, when a row in the DRAM array 404 is detected as defective, the row's contents may be written into a spare row 406. Afterwards, accesses to the defective row are diverted to the spare row including reads, writes, and refreshes. Accordingly, the defective row need not be error corrected, and the DIMM 402 need not be replaced.

The DIMM 402 may also comprise a register 408, which may comprise an address space 410, a row/column indicator 412, and a validity indicator 414. In at least one example, the register 408 is created for the DIMM 402. The address space 410 may be used to contain addresses of defective or error-prone locations in the DRAM array 404 in at least one example. The validity indicator 414 may comprise a flag or a bit that indicates if the address in the address space 410 is valid. For example, the flag or bit may be marked or set to 1 if the address contained in the address space 410 is a valid reference to a location in the DRAM array 404. The flag or bit may be cleared or set to 0 if the address contained in the address space 410 is not a valid reference to a location in the memory array 404. Similarly, the row/column indicator may be a flag, bit, or set of bits that indicate if the address in address space 410 refers to a row or column.

The DIMM 402 may also comprise row selection logic 416 and column selection logic 418. In at least one example, row selection logic 416 selects the spare row to be activated in place of the defective row if one or more conditions are met. The conditions may include: a received address from the address bus equals the value in the address space 410 of the register, the row/column indicator 412 indicates row, the validity indicator 414 indicates a valid register value in the address space 410, and an activate state is commanded for the memory array.

Similarly, column selection logic 418 may select the spare column to read from or written to in place of a defective column if one or more conditions are met. The conditions may include: a received address from the address bus equals the value in the address space 410 of the register, the row/column indicator 412 indicates column, the validity indicator 414 indicates a valid register value in the address space 410, and a read/write state is commanded for the memory array.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An apparatus, comprising:
a memory module, comprising:
a memory array comprising rows of memory and columns of memory;
at least one row of memory not in the memory array;
a register comprising an address space and a row/column indicator;
row selection logic to select the at least one row to be activated if the address from an address bus equals the register value and if the row/column indicator indicates row,

2. The apparatus of claim 1, further comprising:
at least one column of memory not in the memory array; and
column selection logic to select the at least one column to be read from or written to if the address from the address bus equals the register value and if the row/column indicator indicates column.

3. The apparatus of claim 1, tie row selection logic to select the at least one row to be activated if an activate state is commanded for the memory array.

4. The apparatus of claim 2, the column selection logic to select the at least one column to be activated if a read or write state is commanded for the memory array.

5. The apparatus of claim 1, the register further comprising a validity indicator; the row selection logic to select the at least one row if the validity indicator indicates a valid register value.

6. The apparatus of claim 2, the register further comprising a validity indicator, the column selection logic to select the at least one column if the validity indicator indicates a valid register value.

7. The apparatus of claim 1, the register further comprising a validity indicator, wherein comparison of the address and the register value is initiated by the validity indicator indicating a valid register value.

8. A method, comprising;
receiving an address from an address bus, the address representing a location in a memory array, the memory array comprising; rows of memory and columns of memory;
comparing the address to a register value in the address space of a register, the register also comprising a row/column indicator; and
selecting at least one row of memory not in the memory array to be activated if the address from the address bus equals the register value and if the row/column indicator indicates row.

9. The method of claim 8, further comprising:
writing an address of a row of the memory array containing a failure into the register; and
writing the contents of the row of the memory array into the selected at least one row of memory riot in the memory array.

10. The method of claim 8, further comprising maintaining an inventory rows of memory not in the memory array including the at least row of memory not in the memory array.

11. The method of claim 8, further comprising determining an activate state is commanded for the memory array.

12. The method of claim 8, further comprising determining the register contains a valid register value.

13. An apparatus, comprising:
a dual inline memory module (“DIMM”), comprising:
a dynamic random access memory (“DRAM”) array comprising rows of memory and columns of memory;
at least one column of DRAM not in the memory array;
a register comprising an address space and a row/column indicator;
column selection logic to select the at least one column to be read from or written to if the address from an address bus equals the register value and the row/column indicator indicates column.

14. The apparatus of claim 13, the column selection logic to select the at least one column to be read from or written to if a read or write state is commanded for the memory array.

15. The apparatus of claim 13, fie register further comprising a validity indicator, wherein comparison of the address and the register value is initiated by the validity indicator indicating a valid register value.
